(19) United States
(12) Patent Application Publication
(10) Pub. No.: US 2025/0079268 A1
(43) Pub. Date: Mar. 6, 2025

(54) DUAL PACKAGE SWITCHING POWER DEVICE

(71) Applicant: Texas Instruments Incorporated, Dallas, TX (US)

(72) Inventors: Makoto Shibuya, Tokyo (JP); Kwang-Soo Kim, Sunnyvale, CA (US); Woochan Kim, San Jose, CA (US)

(21) Appl. No.: 18/240,614

(22) Filed: Aug. 31, 2023

(51) Int. Cl. H01L 23/495; H01L 21/56; H01L 23/00; H01L 23/31

(52) U.S. Cl. CPC H01L 23/49524; H01L 21/56; H01L 23/3107; H01L 23/49503; H01L 23/49562; H01L 24/92; H01L 24/32; H01L 24/48; H01L 24/73; H01L 2224/32145; H01L 2224/48145; H01L 2224/48245; H01L 2224/73265; H01L 2224/92247

(57) ABSTRACT

An electronic device includes a first semiconductor die attached to a first conductive die attach pad and having a first electronic component, a second semiconductor die attached to a second conductive die attach pad and having a second electronic component, a first package structure that encloses the first semiconductor die and a portion of the first die attach pad, a second package structure that encloses the second semiconductor die and a portion of the second die attach pad, and a conductive metal structure that is electrically connected to the first and second electronic components and extends between the first and second package structures, the conductive metal structure exposed outside the first and second package structures.

### BACKGROUND

Power systems are used in a variety of applications, such as automotive components, industrial systems, computing devices, smart phones, etc. As advanced systems become smaller, power converter designs require smaller footprints, ease of use, and lower cost. All in one power modules are desirable for miniaturization, but considering the cost and flexibility of design, it may be better in some cases to design the power circuit with discrete products, and component product offerings must provide design flexibility and device capability to accommodate different design approaches. Many AC-DC or DC-AC circuits need at least two switching power devices, driver circuitry and passive components in half bridge circuits.

### SUMMARY

In one aspect, an electronic device includes a first semiconductor die attached to a first conductive die attach pad and having a first electronic component, and a second semiconductor die attached to a second conductive die attach pad and having a second electronic component. The electronic device includes a first package structure that encloses the first semiconductor die and a portion of the first die attach pad, and a second package structure that encloses the second semiconductor die and a portion of the second die attach pad, as well as a conductive metal structure that is electrically connected to the first and second electronic components and extends between the first and second package structures, with the conductive metal structure exposed outside the first and second package structures.

In another aspect a system includes a circuit board and an electronic device attached to the circuit board. The electronic device includes a first semiconductor die attached to a first conductive die attach pad and having a first electronic component, and a second semiconductor die attached to a second conductive die attach pad and having a second electronic component. The electronic device includes a first package structure that encloses the first semiconductor die and a portion of the first die attach pad, and a second package structure that encloses the second semiconductor die and a portion of the second die attach pad, as well as a conductive metal structure that is electrically connected to the first and second electronic components and extends between the first and second package structures, with the conductive metal structure exposed outside the first and second package structures.

In a further aspect, a method of fabricating an electronic device includes: attaching a first semiconductor die to a first die attach pad in a first column of a row of a lead frame panel array; attaching a second semiconductor die to a second die attach pad in an adjacent second column of the row of the lead frame panel array; forming a first package structure along the first column that encloses the first semiconductor die; forming a second package structure along the second column that encloses the second semiconductor die; trimming conductive leads along a longitudinal side between the first column and an adjacent third column of the row of the lead frame panel array;

trimming conductive leads along another longitudinal side between the second column and an adjacent fourth column of the row of the lead frame panel array; selectively trimming less than all conductive leads along a further longitudinal side between the first column and the second column of the lead frame panel array to leave a conductive metal structure that is electrically connected to the first and second semiconductor dies and extends between the first and second package structures of the respective first and second columns, the conductive metal structure exposed outside the first and second package structures; and separating the first and second package structures along the row from other rows of the lead frame panel array to separate and electronic device from the lead frame panel array.

### BRIEF DESCRIPTION OF THE DRAWINGS

FIG. 1 is a top perspective view of an electronic device including a half bridge circuit with high and low side transistors in respective portions and a switching node clip extending through a middle portion.

FIG. 1A is a top plan view of the electronic device of FIG. 1.

FIG. 1B is a top plan view of a power conversion system with the electronic device of FIGS. 1 and 1A attached to a circuit board.

FIG. 1C is a simplified schematic diagram of the power conversion system of FIG. 1B.

FIG. 2 is a flow diagram of a method of fabricating an electronic device.

FIGS. 3-8 are partial top plan views of the electronic device of FIGS. 1-1C undergoing fabrication processing in a column and adjacent first and second rows of a lead frame panel array.

FIG. 9 is a top perspective view of another electronic device including a transistor.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for case of description in connection with a particular drawing, where such are not to be construed as limiting with respect to the claims.

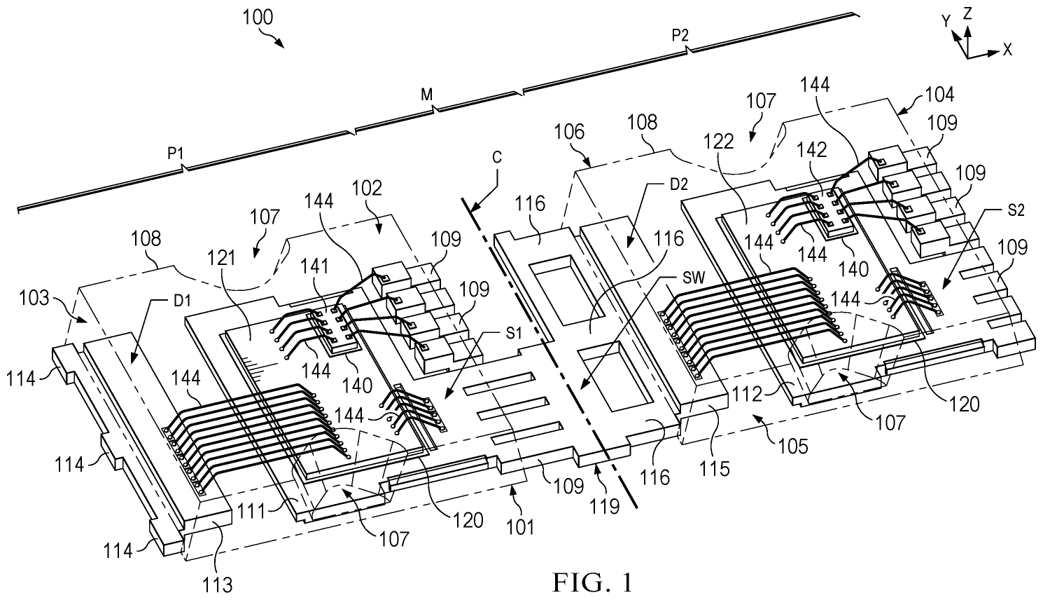

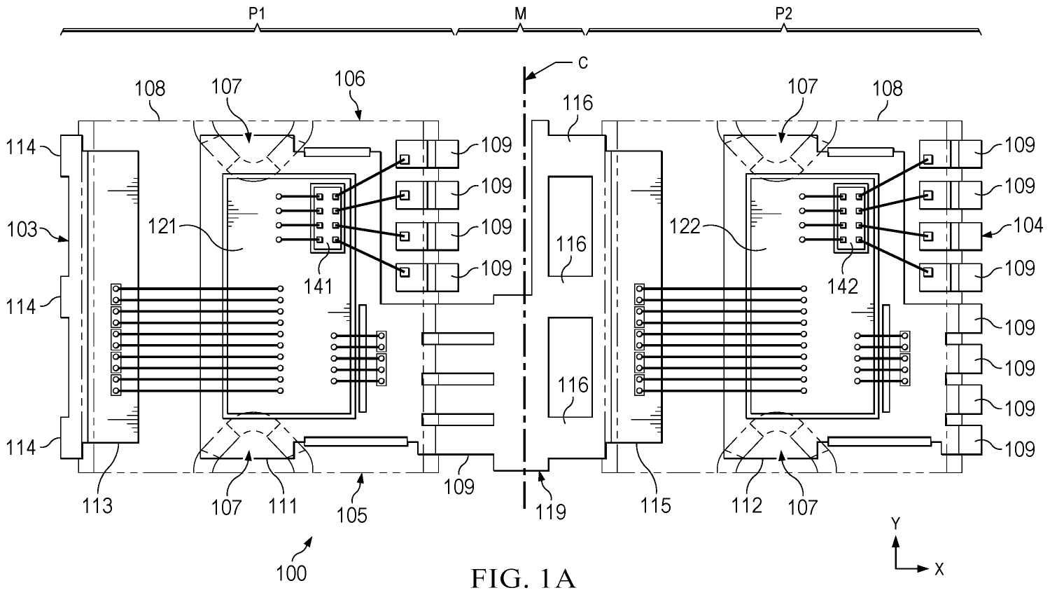

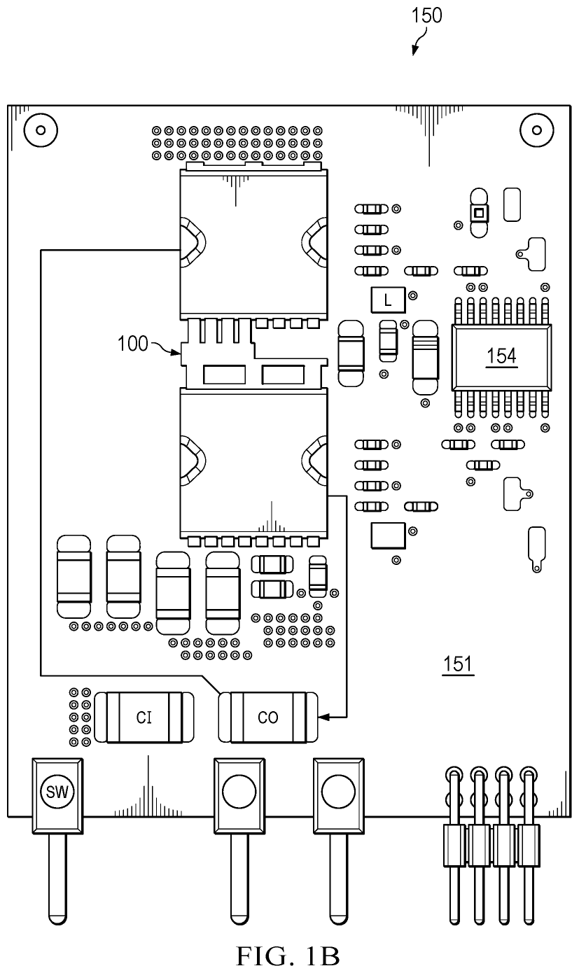

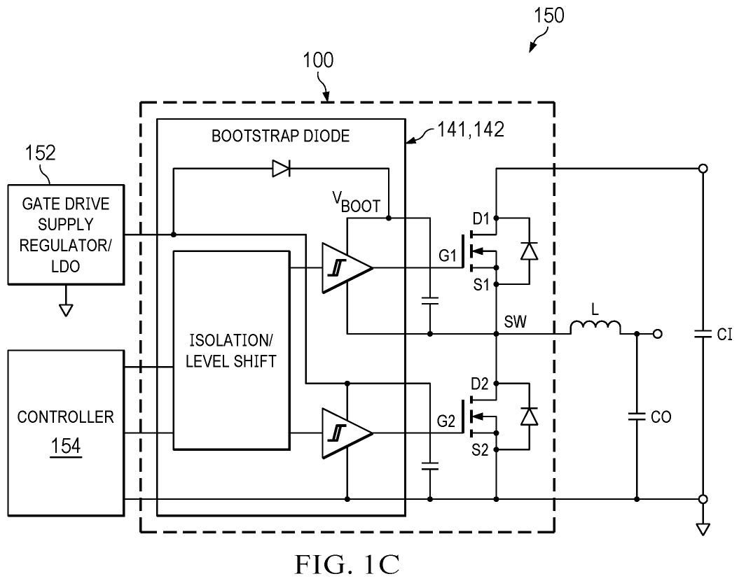

Referring initially to FIGS. 1 and 1A, FIG. 1 shows an electronic device 100 that includes a half bridge circuit with high and low side transistors in respective portions and a switching metal structure that extends through a middle portion in a transistor outline (TO) leadless package arrangement (TOLL) with dual molded package structures 108. FIG. 1A shows a top view of the electronic device 100, FIG. 1B show a top view of a power conversion system with the electronic 100 attached to a circuit board, and FIG. 1C shows a simplified schematic diagram of the power conversion system of FIG. 1B. The electronic device 100 provides modular power stage functionality with two driver and transistor units connected by a switching node conductive metal structure 119 to implement a half bridge module that can be used in a power system.

FIGS. 1 and 1A show the electronic device 100 in an example position in a three-dimensional space with a first direction X, a perpendicular (orthogonal) second direction Y (FIG. 1A), and a third direction Z that is perpendicular (orthogonal) to the respective first and second directions X and Y. Structures or features along any two of these directions are orthogonal to one another.

As shown in FIG. 1, the electronic device 100 has opposite first and second (e.g., bottom and top) sides 101 and 102, respectively, which are spaced apart from one another along the third direction Z in the illustrated orientation. The electronic device 100 has opposite third and fourth sides 103 and 104 (FIGS. 1 and 1A), also referred to herein as longitudinal ends 103 and 104, which are spaced apart from one another along the first direction X and extend along the second direction Y. The electronic device 100 also includes respective fifth and sixth sides 105 and 106, also referred to as opposite lateral sides 105 and 106, which are spaced apart from one another along the second direction Y in the illustrated position.

As best shown in FIGS. 1 and 1A, the electronic device 100 has two molded package structure 108 that form parts of the respective device sides 101-106. The package structures 108 have indents 107 that extend into the lateral sides 105 and 106. In the illustrated example, the respective sides 101-106 are generally planar, the bottom and top sides 101 and 102 extend in respective X-Y planes, and the longitudinal ends 103 and 104 extend in respective Y-Z planes of the second and third directions Y and Z. The electronic device 100 has a middle portion M approximately midway between the longitudinal ends 103 and 104 along a centerline C. The package structure 108 also has a first portion P1 that extends between the middle portion M and one of the longitudinal ends 103 and includes the first package structure 108, and a second portion P2 that extends between the middle portion M and the other one of the longitudinal ends 104 and includes the second package structure 108.

As further shown in FIGS. 1 and 1A, the electronic device 100 has a first set of conductive leads 114 that are partially exposed outside the first package structure 108 along the longitudinal end 103, and a second set of conductive leads 109 that are partially exposed outside the second package structure 108 along the other longitudinal end 104. The illustrated example also includes a third set of conductive leads 109 that are partially exposed outside the first package structure 108 and extend along the first direction X toward the second package structure 108. In the illustrated example, the third set of conductive leads 109 provides signal connections for a driver circuit in the first portion P1, and some of the second set of conductive leads 109 along the longitudinal end 104 provide signal connections for a second driver circuit in the second portion P2. The first set of conductive leads 114 in this example provide a first drain connection for a first transistor component in the first portion P1, and further ones of the second set of conductive leads 109 along the longitudinal end 104 provide a second source connection for a second transistor component in the second portion P2.

The first portion P1 and FIGS. 1 and 1A includes a first conductive metal die attach pad 111, as well as a first transistor drain lead frame portion 113 with the first set of conductive leads 114 along the lateral end 103. The second portion P2 includes a second conductive metal die attach pad 112 with connections to the further ones of the second set of conductive leads 109 along the longitudinal end 104. The second portion P2 also includes a second transistor drain lead frame portion 115 with untrimmed (e.g., uncut) conductive lead structures 116. The first portion P1 also includes untrimmed conductive lead structures labeled 109 in FIGS. 1 and 1A that are contiguous with the first conductive metal die attach pad 111. The lead structures 109, 114, and 116, as well as the die attach pads 111 and 112 and the lead frame portions 113 and 115 in one example are or include copper or other suitable conductive metal.

In one example, the bottoms of the conductive leads 109, 114, and 116, the bottom sides of the conductive metal die attach pads 111 and 112, and the bottom sides of the and the lead frame portions 113 and 115, are exposed outside the respective package structures 108 along the first or bottom side 101 of the electronic device 100. In use in a host system (e.g., FIG. 1B below), the bottoms of the conductive leads 109, 114, and 116 can be soldered to corresponding conductive metal features (e.g., pads) of a host circuit board to provide electrical connections to circuitry of the electronic device 100, and one or more of the bottom sides of the conductive metal die attach pads 111 and 112, and the bottom sides of the lead frame portions 113 and 115 can also be soldered to a host circuit board. In addition, the sides of one or more of the conductive leads 109, 114, and/or 116 can accommodate adherence to solder, for example, to facilitate solder wetting and proper solder connections during attachment of the electronic device 100 to a host circuit board.

As further shown in FIGS. 1 and 1A, the electronic device include a conductive metal structure 119 that extends between the first and second package structures 108 and is exposed outside the package structures 108 in the middle portion M. The electronic device 100 includes a first semiconductor die 121 that is attached by solder 120 (FIG. 1) to the first conductive metal die attach pad 111 and is enclosed by the first package structure 108 in the first portion P1. The electronic device 100 also includes a second semiconductor die 122 attached by solder 120 (FIG. 1) to the second conductive metal die attach pad 112 in the second portion P2.

The first and second semiconductor dies 121 and 122 can be or include any suitable semiconductor material, such as silicon, gallium nitride, etc. The first and second semiconductor dies 121 and 122 have respective first and second transistor electronic components (e.g., field effect transistors Q1 and Q2 schematically illustrated in FIG. 1C below). The transistor Q1 in FIG. 1C (e.g., of the first semiconductor die 121 in FIGS. 1 and 1A) is configured as a high side transistor and a half bridge circuit that includes a first drain D1 and a first source S1 with schematic connections illustrated in the first portion P1 FIG. 1, as well as a first gate G1 (FIG. 1C). The second transistor Q2 in this example is configured as a low side transistor of the half bridge circuit that has a second drain D2, a second source S1, and a second gate G2.

The conductive metal structure 119 is electrically connected to the first and second electronic components Q1 and Q2. In the illustrated example, the conductive metal structure 119 and the first die attach pad 111 are a contiguous metal structure.

As further shown in FIGS. 1 and 1A, the electronic device 100 also includes bond wires 144 that form electrical connections. The illustrated example includes bond wires 144 to form an electrical connection between the first transistor drain lead frame portion 113 and conductive drain terminals on the top side of the first semiconductor die 121 to provide a first drain connection D1 to the conductive leads 114 along the longitudinal end 103 of the electronic device 100. Another set of bond wires 144 in this example is attached to form an electrical connection between a first pair of the conductive leads 109 of the second portion P2 and conductive source terminals on the top side of the second semiconductor die 122 to provide the second source connection S2 along the longitudinal end 106 of the electronic device 100. In another implementation, metal clip connections (not shown) can be used to provide the electrical interconnections of the first drain D1 and/or the second source S2, and the associated bond wires can be omitted.

The electronic device 100 in the illustrated example also includes onboard driver circuitry, with a first driver die 141 enclosed by the first package structure 108 and attached by an adhesive 140 (e.g., epoxy) to a portion of the top side of the first semiconductor die 121 in the first portion P1. The electronic device also includes a second driver die 142 enclosed by the second package structure 108 and attached by adhesive 140 to a portion of the top side of the second semiconductor die 122 in the second portion P2.

The electronic device 100 also includes bond wires 144 (numerically designated in FIG. 1 and also shown in FIG. 1A) that are enclosed by respective ones of the first and second package structures. The bond wires 144 form electrical circuit connections between the respective driver dies 141 and 142 and the transistor electronic components of the semiconductor dies 121 and 122, as well as connections to respective ones of the conductive leads 109, 114, 116, for example, to allow transistor terminal connections and connection of the transistor switching control signals from other components or systems of a host printed circuit board. In another example, one or more conductive metal clips (not shown) can be used to form one or more electrical circuit connections in either or both of the portions P1 and/or P2, alone or in combination with one or more bond wires 144.

The conductive metal structure 119 electrically couples a source of the first electronic component Q1 of the first semiconductor die 121 to a drain of the second transistor Q2 of the second semiconductor die 122 to form a switching node SW of a half bridge circuit. The electronic device 100 provides an integrated half bridge transistor circuit that can be used as a module in constructing a variety of different power converter architectures, providing a compact module that can be integrated with other external components, for example, on a host printed circuit board, as illustrated and described further below in connection with FIGS. 1B and 1C.

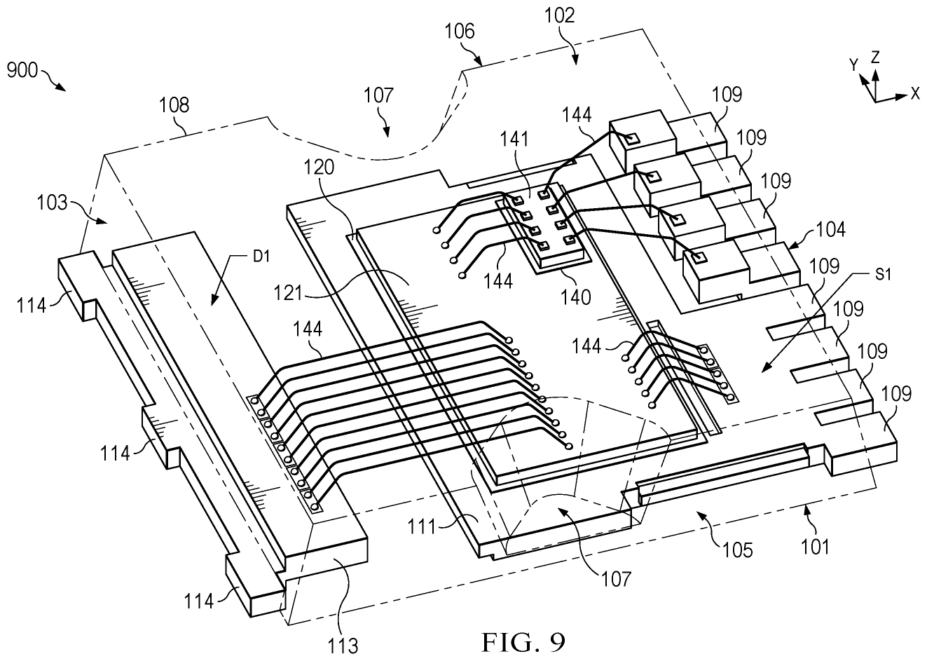

It is further noted that the illustrated structure can be modified by cutting along the centerline C to provide to separate single transistor modules that can be used as components in a power converter or other transistor circuit, for example, as illustrated and described further below in connection with FIG. 9.

The conductive metal structure 119 in the electronic device 100 advantageously provides interconnection of the high and low side circuitry in the respective first and second portions P1 and P2 by a conductive metal switching node structure that can carry high currents associated with power conversion circuitry. In this regard, the conductive metal structure 119 can be constructed of copper or other suitable metal having a thickness and shape that supports switching node current flow in operation and can be the same as the thickness of the structures 109 and 111-116 of a starting lead frame to advantageously utilize existing lead frame structures (e.g., having a thickness of approximately 0.5 mm). The electronic device 100 and variants thereof also facilitate sharing of tools and machinery with other power conversion system components and modules in constructing half bridge in full bridge power conversion systems and other circuit topologies.

The illustrated example, moreover, provides a modular half bridge module using a transistor outline leadless (TOLL) structure for compact system designs, while providing high switching node current capability compared with standard printed circuit board copper traces to interconnect a switching node with an inductor or other power converter components. The TOLL package of the illustrated example facilitates use in high current applications, such as automotive systems, industrial systems, computers, smart phones, battery chargers, etc., and can facilitate high power applications with good efficiency, low electromagnetic interference (EMI) performance and/or good thermal performance in compact high circuit density applications.

In addition, the conductive metal structure 119 and the high current capability of the various circuit nodes of the electronic device 100 advantageously facilitate low parasitic inductance, low impedance, and improved thermal performance in power conversion and other system applications. The modular construction of the electronic device 100 can help reduce component count, cost, and circuit area in a surface mount technology (SMT) implementation of a host printed circuit board and allow case of manufacturing and low cost for end-users.

Referring also to FIGS. 1B and 1C, FIG. 1B shows a top view of a power conversion system 150 with the electronic device 100 attached to a circuit board 151, and FIG. 1C shows a simplified schematic diagram of the power conversion system 150. In this example, the conductive leads 109, 114, and 116 of the electronic device 100 are soldered to corresponding conductive pads on the top side of the circuit board 151 along with other components on the top side of the circuit board 151 using a conventional surface mount technology process.

The example power conversion circuit in FIG. 1C includes a gate drive supply regulator 152, such as a low dropout (LDO) circuit formed by various components on the circuit board 151 of FIG. 1B, as well as a controller chip 154 implemented as another electronic device soldered to the circuit board 151 as shown in FIG. 1B. The circuit board 151 also includes various passive components, such as input and output capacitors CI and CO, respectively, a switching inductor L connected between an output node and the switching node SW, and various terminals to allow connection of power and control signals to the circuit board 151.

The electronic device 100 in this example includes the onboard driver circuit dies 141 and 142 that can implement gate driver circuits, a bootstrapped diode, isolation and level shifting circuitry, etc. of the buck converter circuit shown in FIG. 1C. As noted above, the provision of separate driver dies 141 and 142 in the respective first and second portions P1 and P2 of the electronic device 100 facilitates selective cutting along the centerline C in order to selectively provide individual single transistor modules that can (but need not) be interconnected in a half bridge circuit. In another implementation, a single driver die (not shown) can be provided in the half bridge electronic device 100 in either the first or second portions P1, P2, or such a single driver die can extend at least partially in the middle portion M or in any two or more of the illustrated portions P1, P2, and M.

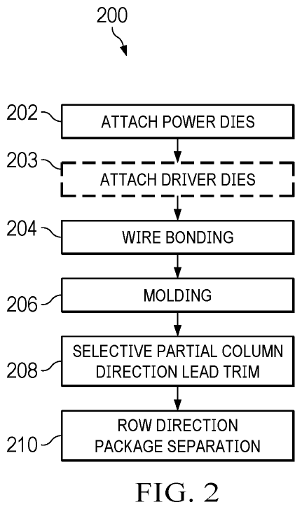

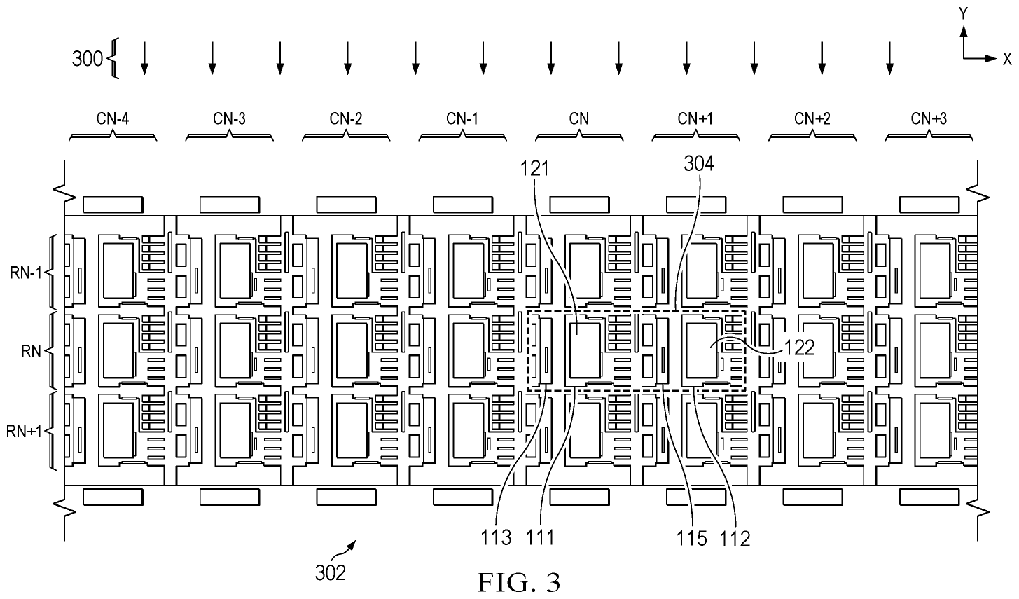

Referring now to FIGS. 2-8, FIG. 2 shows a method 200 of fabricating an electronic device. and FIGS. 3-8 show the electronic device 100 undergoing fabrication processing in a first row and adjacent first and second columns of a lead frame panel array, as well as other electronic devices undergoing concurrent fabrication processing in the lead frame panel array.

The method 200 begins with a starting lead frame panel array with conductive metal features (e.g., copper, aluminum, etc.) formed in rows R and columns C. FIG. 3 shows a portion of an example lead frame panel array 302, with a single, composite unit area 304 that includes two adjacent (e.g., first and second) columns CN and CN+1 in a first row RN along with portions of neighboring rows RN−1 and RN+1 and columns CN−4, CN−3, CN−2, CN−1, CN+2, and CN+3 in an array configuration. In this example, the example first column CN of the first row RN in the illustrated unit area 304 corresponds to the first portion P1 of the prospective electronic device 100 described above, and the second column CN+1 of the row RN corresponds to the second portion P2 of the prospective electronic device 100 described above.

The method 200 in FIG. 2 includes die attach processing at 202, including attachment of the first and second (e.g., power) semiconductor dies 121 and 122. The die attach processing at 202 and other processing steps of the method 200 are shown in the drawings with respect to the illustrated unit area 304 and the designated first row RN, and these processing steps can include similar processing in other unit areas of the lead frame panel array 302 that are not shown in the drawings.

FIG. 3 shows one example, in which a die attach process 300 is performed that attaches the first semiconductor die 121 to the first die attach pad 111 in the first column CN of the row RN of the lead frame panel array 302. The die attach process 300 also attaches the second semiconductor die 122 to the second die attach pad 112 in the adjacent column CN+1 of the row RN of the lead frame panel array 302. The die attach process 300 can also include attaching other semiconductor dies in other unit areas of the lead frame panel array 302, for example, by dispensing, printing, or otherwise providing solder and other electronic devices or conductive or nonconductive adhesive in select portions of top sides of certain lead frame features, as well as placement of semiconductor dies and corresponding locations on the solder paste or adhesive (e.g., using automated pick and place equipment, not shown), and subsequent solder reflow and/or curing processing (e.g., thermal reflow, thermal adhesive curing, UV adhesive curing, etc.) to adhere the semiconductor dies to the corresponding locations of the lead frame panel array.

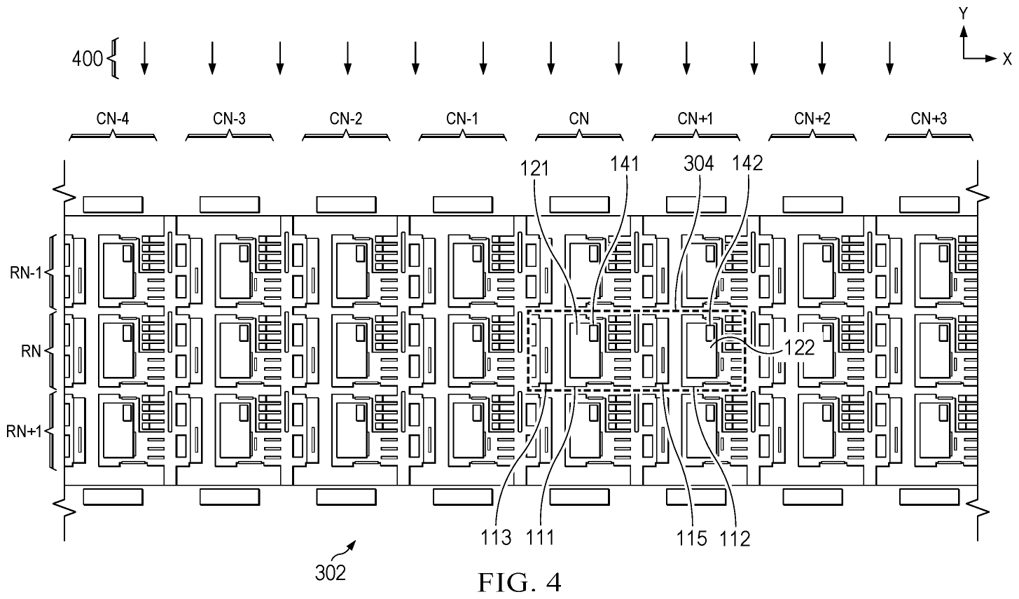

The method 200 continues at 203 in FIG. 2 with optional driver die attachment. FIG. 4 shows one example, in which another die attach process 400 is performed that attaches the driver dies 141 and 142 in the respective columns CN and CN+1 of the illustrated first row RN, as well as in other unit areas of the lead frame panel array 302. In one implementation, the die attach process 400 includes dispensing an adhesive (e.g., adhesive 140 in FIG. 1 above), and selective automated placement of the driver dies 141 and 142 in the designated portions of the top sides of the respective first and second semiconductor dies 121 and 122, along with any suitable adhesive curing step or steps (e.g., thermal, UV, etc.).

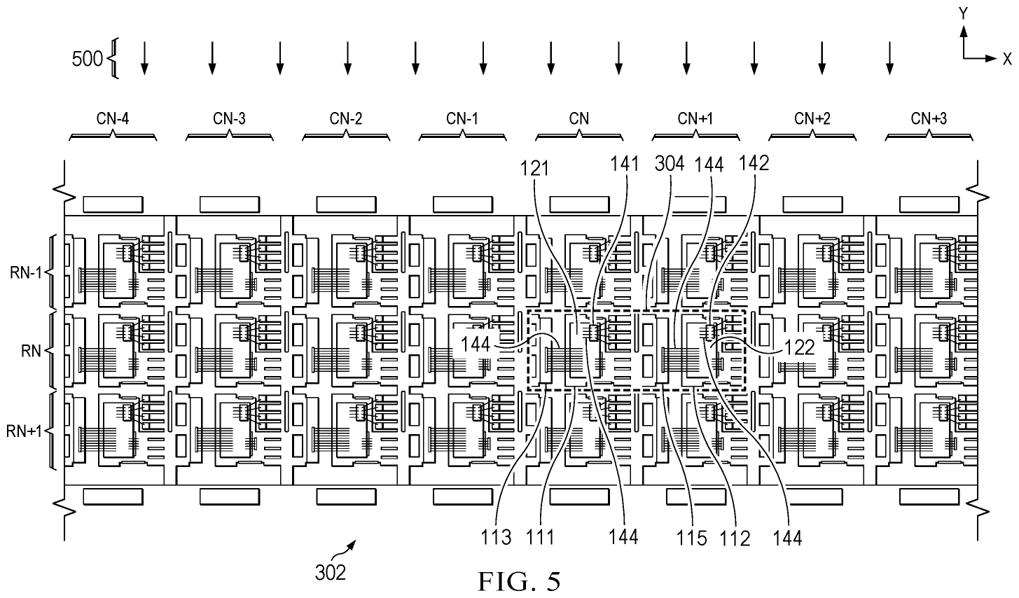

The method 200 continues at 204 in FIG. 2 with wire bonding or other electrical connection processing, such as via conductive metal clips. FIG. 5 shows one example, in which a wire bonding process 500 is performed that creates the bond wires 144 for the electrical circuit connections of the semiconductor dies 121 and the 122, the driver dies 141 and 142 and any other desired electrical interconnections as discussed above. In another implementation, further and/or different bond wires (not shown) and/or soldered metal clips can be created and/or installed at 204, for example, to provide connections between one or more transistor die terminals and corresponding leads in the unit area 304, such as in lieu of or in addition to the electrical connections provided by the illustrated bond wires 144.

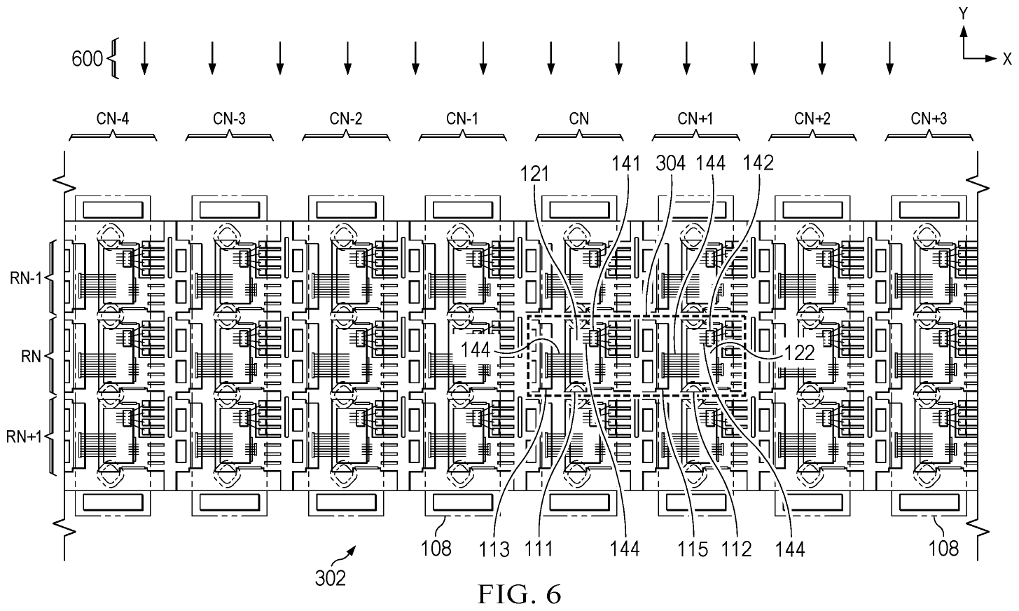

The method 200 continues at 206 in FIG. 2 with molding processing to form the molded package structure 108 along columns C of the lead frame panel array 302. FIG. 6 shows one example, in which a molding process 600 is performed using a mold with downwardly extending features between adjacent columns and posts to form the above-described package structure indents 107.

In the illustrated example, the downwardly extending posts engage certain portions of the first and second die attach pads 111 and 112 in the illustrated unit area 304 and other die attach pad structures in other rows and columns of the lead frame panel array 302, for example, to allow proper flow of the molding compound 108 during mold filling operations such that the bottoms of the illustrated die attach pads 111 and 112 are not covered with molding material and will ultimately be exposed outside the bottom side 101 of the finished electronic device 100 (e.g., FIG. 1 above). FIG. 6 illustrates the described portion of the lead frame panel array 302 following removal of the upper mold structure, where the molding process 600 creates openings that expose portions of the conductive metal die attach pads 111 and 112.

In the illustrated example, moreover, the mold features may engage the switching node metal structure 119, and the column length molded package structures 108 expose the conductive metal structure 119 in the illustrated unit area 304, although not a strict requirement of all possible implementations. The illustrated example forms the package structures 108 as a continuous molded structure that extends along each of the columns of the lead frame panel array 302, and the column length molded package structures 108 in the example first and second columns CN and CN+1 enclose the respective first and second semiconductor dies 121 and 122 and the bond wires 144 in the illustrated unit area 304.

At 208 in FIG. 2, the method 200 continues with selective partial column direction lead trimming. In the illustrated example, the prospective electronic device 100 is a leadless structure, with the bottoms of the conductive leads 109, 114, and 116 and the conductive metal structure 119 being adapted for soldering to a host printed circuit board. In another example, other forms of leads and corresponding lead frame structures can be used, for instance, to form gullwing leads, J type leads, etc., and the processing at 208 can include both lead trimming and forming.

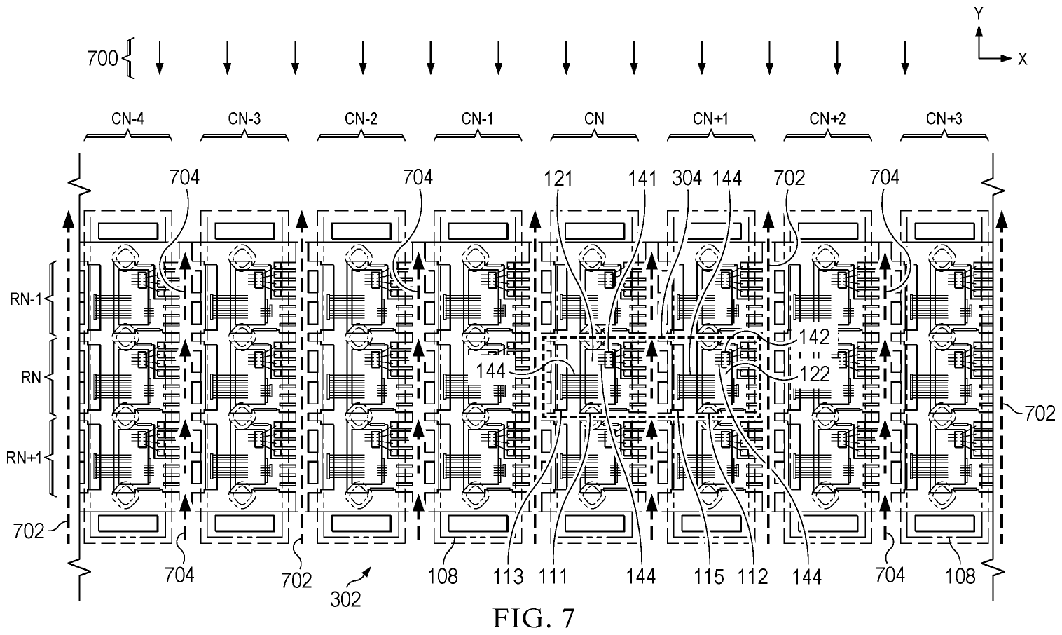

FIG. 7 shows one example, in which certain of the prospective leads of the lead frame panel array 302 are trimmed by a process 700 (e.g., cut), for example, using saw cutting, laser cutting, chemical etching, or other suitable cutting or trimming processing, to separate the structures of the illustrated columns CN and CN+1 from the adjacent or neighboring columns CN−1 and CN+2 and to selectively trim certain of the interior leads 109 between the illustrated columns CN and CN+1 while refraining from separating the conductive metal structure 119 between the first and second package structures 108 of the illustrated columns CN and CN+1.

In the illustrated example, starting lead frame metal features along the boundaries between alternating columns are trimmed or cut completely along cut lines 702, whereas starting lead frame metal features along the boundaries between the other columns (e.g., including between the illustrated columns CN and CN+1) are only partially cut along the cut lines 704 in FIG. 7. The selective cutting in one example is performed by suitable punch die tooling (not shown). Other suitable tooling and equipment can be used in other implementations. The separation process 700 in another example can be performed by automated and/or reconfigurable blade cutting equipment (not shown) that can selectively cut or not cut between designated pairs of adjacent columns and/or portions thereof in one or more of the rows of the lead frame panel array 302. For example, insertion of a corresponding partial cutting blade between the column CN and CN+1 can allow selective separation of the third set of conductive leads 109 (e.g., FIG. 1 above) while leaving the corresponding conductive metal structure 119 uncut in the illustrated unit area of 304, while insertion of a full cutting blade in another portion of the lead frame panel array can allow concurrent separation of adjacent single transistor electronic devices (e.g., FIG. 9 below). This selectivity allows cost effective selectable manufacturing of single transistor devices and/or composite half bridge electronic devices 100 for a given lead frame panel array processing sequence with little or no added cost or complexity.

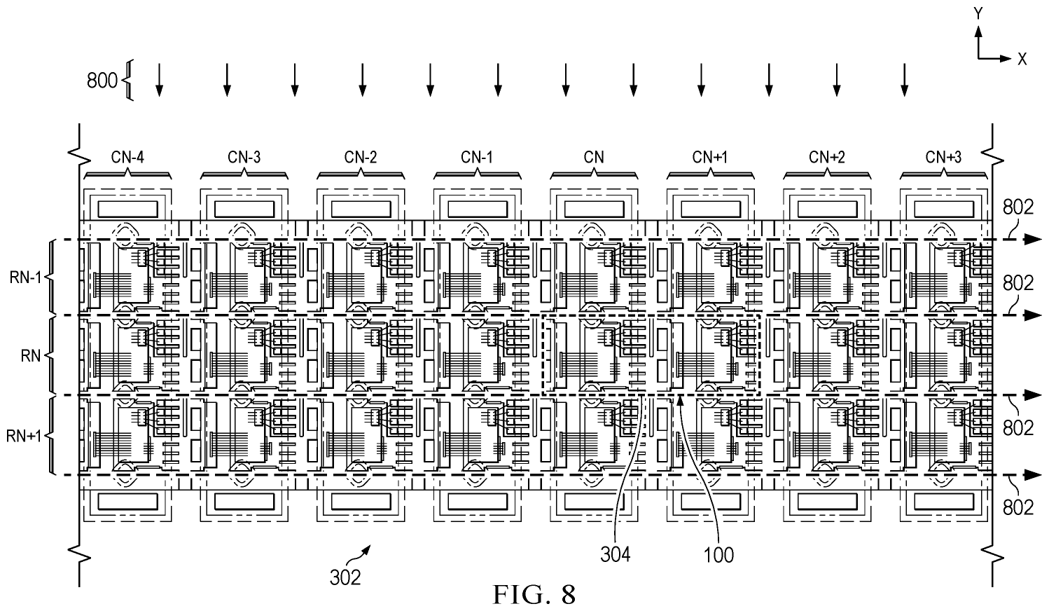

The method 200 continues at 210 in FIG. 2 with row direction package separation. FIG. 8 shows one example of suitable separation processing, in which a row direction cutting or separation process 800 is performed (e.g., saw cutting, laser cutting, chemical etching, etc.) that cuts through the molded package structures 108 along the lines 802. As shown in FIG. 8, the process 800 separates the packaged electronic device 100 from the lead frame panel array 302 and the process 800 cuts along the lines 802 between all adjacent rows of the lead frame panel array 302.

FIG. 9 shows an example of another electronic device 900 including a transistor in a single instance of the first semiconductor die 121 and other structural features as described above with respect to the first portion P1 of the example electronic device 100 of FIGS. 1-1C. The electronic device 900 in this example provides a single transistor module, optionally including the onboard driver die 141, with suitable conductive metal leads 109 and 114 exposed along the sides 103 and 104 to allow suitable electrical connection of the transistor of the semiconductor die 121 and the driver circuitry of the driver die 141 to a host circuit board, for example, in a half or full bridge circuit with other components, or as a single transistor. The method 200 in the illustrated lead frame panel array design 302 allow selective manufacturing of single transistor devices 900 concurrently with fabrication of half bridge module electronic devices 100 as described above.

Modifications are possible in the described examples, and other implementations are possible, within the scope of the claims.

What is claimed is:

1. An electronic device, comprising:
a first semiconductor die attached to a first conductive die attach pad and having a first electronic component;
a second semiconductor die attached to a second conductive die attach pad and having a second electronic component;
a first package structure that encloses the first semiconductor die and a portion of the first die attach pad;
a second package structure that encloses the second semiconductor die and a portion of the second die attach pad; and
a conductive metal structure that is electrically connected to the first and second electronic components and extends between the first and second package structures, the conductive metal structure exposed outside the first and second package structures.

2. The electronic device of claim 1, comprising:
opposite longitudinal ends spaced apart from one another along a first direction;
opposite lateral sides spaced apart from one another along a second direction that is orthogonal to the first direction;
a middle portion midway between the longitudinal ends;
a first portion that extends between the middle portion and one of the longitudinal ends and includes the first semiconductor die, the first conductive die attach pad, the first package structure, and a first set of conductive leads that are partially exposed outside the first package structure along the one of the longitudinal ends; and
a second portion that extends between the middle portion and the other one of the longitudinal ends and includes the second semiconductor die, the second conductive die attach pad, the second package structure, and a second set of conductive leads that are partially exposed outside the second package structure along the other one of the longitudinal ends;
wherein the conductive metal structure extends through the middle portion between the first and second portions.

3. The electronic device of claim 2, wherein bottom sides of the first and second die attach pads are exposed outside bottom sides of the respective first and second package structures.

4. The electronic device of claim 2, comprising a third set of conductive leads that are partially exposed outside the first package structure and extend along the first direction toward the second package structure.

5. The electronic device of claim 1, wherein the conductive metal structure and the first die attach pad are a contiguous structure.

6. The electronic device of claim 5, comprising conductive leads that are partially exposed outside the first package structure and extend along the first direction toward the second package structure.

7. The electronic device of claim 1, wherein:
the first electronic component of the first semiconductor die is a first transistor;
the second electronic component of the second semiconductor die is a second transistor; and
the conductive metal structure electrically couples a source of the first transistor to a drain of the second transistor to form a switching node of a half bridge circuit.

8. A system, comprising:
a circuit board; and
an electronic device attached to the circuit board and comprising:
a first semiconductor die attached to a first conductive die attach pad and having a first electronic component;
a second semiconductor die attached to a second conductive die attach pad and having a second electronic component;
a first package structure that encloses the first semiconductor die and a portion of the first die attach pad;
a second package structure that encloses the second semiconductor die and a portion of the second die attach pad; and
a conductive metal structure that is electrically connected to the first and second electronic components and extends between the first and second package structures, the conductive metal structure exposed outside the first and second package structures.

9. The system of claim 8, wherein the electronic device comprises:
opposite longitudinal ends spaced apart from one another along a first direction;
opposite lateral sides spaced apart from one another along a second direction that is orthogonal to the first direction;
a middle portion midway between the longitudinal ends;
a first portion that extends between the middle portion and one of the longitudinal ends and includes the first semiconductor die, the first conductive die attach pad, the first package structure, and a first set of conductive leads that are partially exposed outside the first package structure along the one of the longitudinal ends and soldered to the circuit board; and
a second portion that extends between the middle portion and the other one of the longitudinal ends and includes the second semiconductor die, the second conductive die attach pad, the second package structure, and a second set of conductive leads that are partially exposed outside the second package structure along the other one of the longitudinal ends and soldered to the circuit board;
wherein the conductive metal structure extends through the middle portion between the first and second portions.

10. The system of claim 9, wherein bottom sides of the first and second die attach pads are exposed outside bottom sides of the respective first and second package structures and soldered to the circuit board.

11. The system of claim 9, wherein:
the electronic device comprises a third set of conductive leads that are partially exposed outside the first package structure and extend along the first direction toward the second package structure; and
the third set of conductive leads are soldered to the circuit board.

12. The system of claim 8, wherein the conductive metal structure and the first die attach pad are a contiguous structure.

13. The system of claim 12, wherein:
the electronic device comprises conductive leads that are partially exposed outside the first package structure and extend along the first direction toward the second package structure; and
the conductive leads are soldered to the circuit board.

14. The system of claim 8, wherein the conductive metal structure is soldered to the circuit board.

15. The system of claim 8, wherein:
the first electronic component of the first semiconductor die is a first transistor;
the second electronic component of the second semiconductor die is a second transistor; and
the conductive metal structure electrically couples a source of the first transistor to a drain of the second transistor to form a switching node of a half bridge circuit.

16. A method of fabricating an electronic device, the method comprising:
attaching a first semiconductor die to a first die attach pad in a first column of a row of a lead frame panel array;
attaching a second semiconductor die to a second die attach pad in an adjacent second column of the row of the lead frame panel array;
forming a first package structure along the first column that encloses the first semiconductor die;
forming a second package structure along the second column that encloses the second semiconductor die;
trimming conductive leads along a longitudinal side between the first column and an adjacent third column of the row of the lead frame panel array;
trimming conductive leads along another longitudinal side between the second column and an adjacent fourth column of the row of the lead frame panel array;
selectively trimming less than all conductive leads along a further longitudinal side between the first column and the second column of the lead frame panel array to leave a conductive metal structure that is electrically connected to the first and second semiconductor dies and extends between the first and second package structures of the respective first and second columns, the conductive metal structure exposed outside the first and second package structures; and
separating the first and second package structures along the row from other rows of the lead frame panel array to separate and electronic device from the lead frame panel array.

17. The method of claim 16, further comprising, before forming the first and second package structures:
electrically connecting a first electronic component of the first semiconductor die to the conductive metal structure; and
electrically connecting a second electronic component of the second semiconductor die to the conductive metal structure.

18. The method of claim 17, wherein:
electrically connecting the first electronic component to the conductive metal structure includes wire bonding a terminal of the first electronic component to a portion of the conductive metal structure in the first column of the row of the lead frame panel array; and
electrically connecting the second electronic component to the conductive metal structure includes wire bonding a terminal of the second electronic component to a portion of the conductive metal structure in the second column of the row of the lead frame panel array.

19. The method of claim 17, further comprising, before forming the first and second package structures:
electrically connecting the first semiconductor die to one of the conductive leads along the longitudinal side; and
electrically connecting the second semiconductor die to one of the conductive leads along the other longitudinal side.

20. The method of claim 16, further comprising, before forming the first and second package structures:
attaching a first driver die to a side of the first semiconductor die; and
attaching a second driver die to a side of the second semiconductor die.
